(19) United States
(12) Patent Application Publication
(10) Pub. No.: US 2011/0254648 A1
(43) Pub. Date: Oct. 20, 2011

(54) MOVABLE TRANSFORMER EMBEDDED INTO AN OPENING OF A PCB AND A METHOD OF INSTALLING THE SAME

(75) Inventors: CHUN-KONG CHAN, Hsin Chuang City (TW); Kuo-Jen Hsieh, Hsin Chuang City (TW)

(73) Assignee: LIEN CHANG ELECTRONIC ENTERPRISE CO., LTD.

(21) Appl. No.: 12/761,217

(22) Filed: Apr. 15, 2010

(51) Int. Cl. H01F 21/06; H05K 3/30

(52) U.S. Cl. 336/131; 29/832

(57) ABSTRACT

A movable transformer embedded into an opening of a PCB includes a first bobbin unit, a second bobbin unit, a third bobbin unit, a winding unit and a magnetic unit. The second bobbin unit is electrically connected to the PCB. The third bobbin unit is electrically connected to the PCB. The winding unit is disposed around the first bobbin unit, the second bobbin unit and the third bobbin unit. The magnetic unit passes through the first bobbin unit and disposed outside the first bobbin unit. In addition, one side of the first bobbin unit is slidably mated with the second bobbin unit, another side of the first bobbin unit is slidably mated with the third bobbin unit, so that the first bobbin unit is selectively moved from one position above the opening to another position in the opening.

### BACKGROUND OF THE INVENTION

1. Field of the Invention

The present invention relates to a movable transformer and a method of installing the same, in particular, to a movable transformer embedded into an opening of a PCB (Printed. Circuit Board) and a method of installing the same.

2. Description of Related Art

As the technology develops, the trends of all kinds of electronic devices have been directed toward miniaturization and light weight. Internal electronic devices also develop toward miniaturization. However, many problems occur in the process of miniaturizing electronic devices.

Take transformers as an example. It has been over a century since transformers were first manufactured by a Hungarian company called GANZ in 1885. Transformers are widely used for a long time and have evolved into many types of transformers. However, the principles are still unchanged. Transformers transfer electrical energy to/from magnetic energy. Two sets of coils are wound on a common iron core. The coil connected to a power terminal is called primary coil, and the coil connected to a load terminal is called secondary coil. Or, the coils can also be called as high voltage coil and low voltage coil based on the voltage magnitude. The primary coil can be the high voltage coil or the low voltage coil depending on the voltage magnitude. When the primary coil is connected to an alternating current power source, the current passing through the coil generates a change in the magnetic flux. The secondary coil at the other end generates alternating current with the same frequency due to induced electromotive force.

Moreover, there are many methods for decreasing occupied space above a PCB by a transformer in the related art. For example, decreasing the size of the transformer. However, the magnetic-energy-storage would be decreased greatly due to the decrease of the size of the transformer. Hence, it is difficult for designer to design a miniaturization transformer with enough magnetic-energy-storage.

### SUMMARY OF THE INVENTION

In view of the aforementioned issues, the present invention provides a movable transformer and a method of installing the same in order to embed the movable transformer into an opening of a PCB.

To achieve the above-mentioned objectives, the present invention provides a movable transformer embedded into an opening of a PCB, including: a first bobbin unit, a second bobbin unit, a third bobbin unit, a winding unit and a magnetic unit. The second bobbin unit is electrically connected to the PCB. The third bobbin unit is electrically connected to the PCB. The winding unit is disposed around the first bobbin unit, the second bobbin unit and the third bobbin unit. The magnetic unit passes through the first bobbin unit and disposed outside the first bobbin unit. In addition, one side of the first bobbin unit is slidably mated with the second bobbin unit, another side of the first bobbin unit is slidably mated with the third bobbin unit, so that the first bobbin unit is selectively moved from one position above the opening to another position in the opening.

To achieve the above-mentioned objectives, the present invention provides a method of installing a movable transformer, including: providing a PCB, wherein the PCB has a removing portion; electrically connecting the movable transformer to the PCB, wherein the movable transformer has a fixing unit electrically disposed on the PCB, a movable unit disposed above the removing portion and being movable relative to the fixing unit, a magnetic unit jointed with the fixing unit and a winding unit disposed around the fixing unit and the movable unit; fixing the movable transformer on the PCB and removing the removing portion from the PCB in order to form an opening on the PCB; and pressing the movable unit to move downwards the movable unit relative to the fixing unit and receive the movable unit in the opening.

Therefore, one side of the first bobbin unit is slidably mated with the second bobbin unit and another side of the first bobbin unit is slidably mated with the third bobbin unit, so that the first bobbin unit may be moved upwards or downwards between the second bobbin unit and the third bobbin unit and the first bobbin unit may be selectively moved from one position above the opening to another position in the opening. Hence, the present invention not only can decrease the occupied space above the PCB by the movable transformer, but also can maintain original magnetic-energy-storage.

In order to further understand the techniques, means and effects the present invention takes for achieving the prescribed objectives, the following detailed descriptions and appended drawings are hereby referred, such that, through which, the purposes, features and aspects of the present invention may be thoroughly and concretely appreciated; however, the appended drawings are provided solely for reference and illustration, without any intention that they be used for limiting the present invention.

### BRIEF DESCRIPTION OF THE DRAWINGS

FIGS. 1A to 1G are schematic views of a method of installing a movable transformer according to the present invention, at different stages of the installing processes, respectively;

FIG. 2A is a top, exploded, schematic view of the first, the second and the third bobbin units according to the present invention;

FIG. 2B is a lateral, schematic view of one side of the movable transformer according to the present invention;

FIG. 2C is a lateral, schematic view of another side of the movable transformer according to the present invention; and

FIG. 3 is a lateral, schematic view of the movable transformer embedded according to another embodiment of the present invention.

### DETAILED DESCRIPTION OF THE PREFERRED EMBODIMENTS

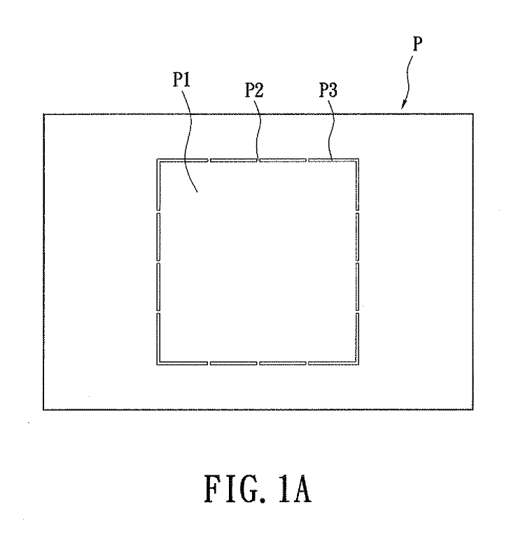

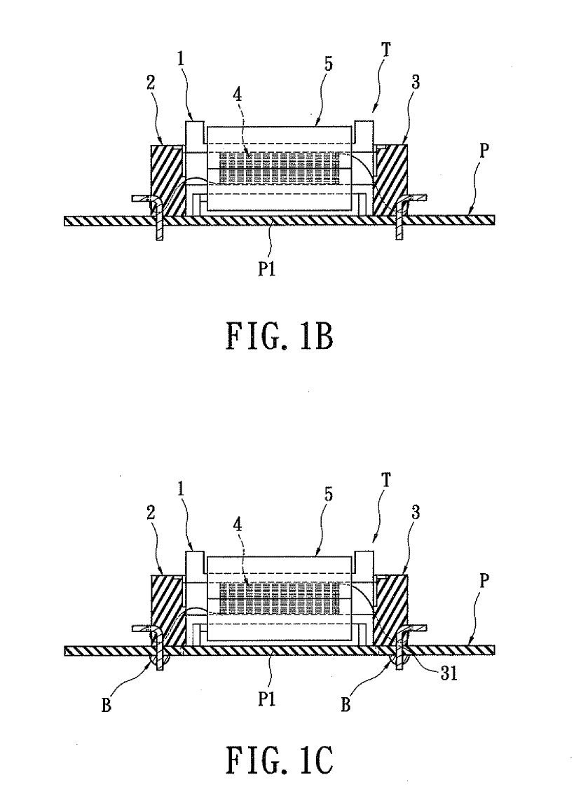

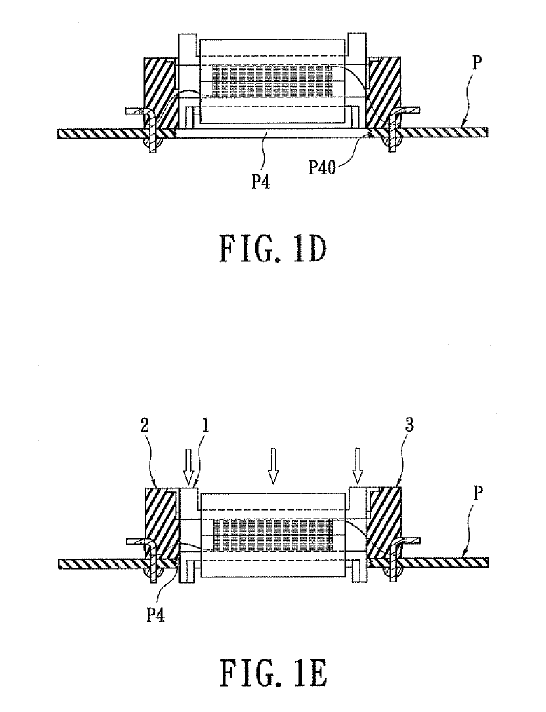

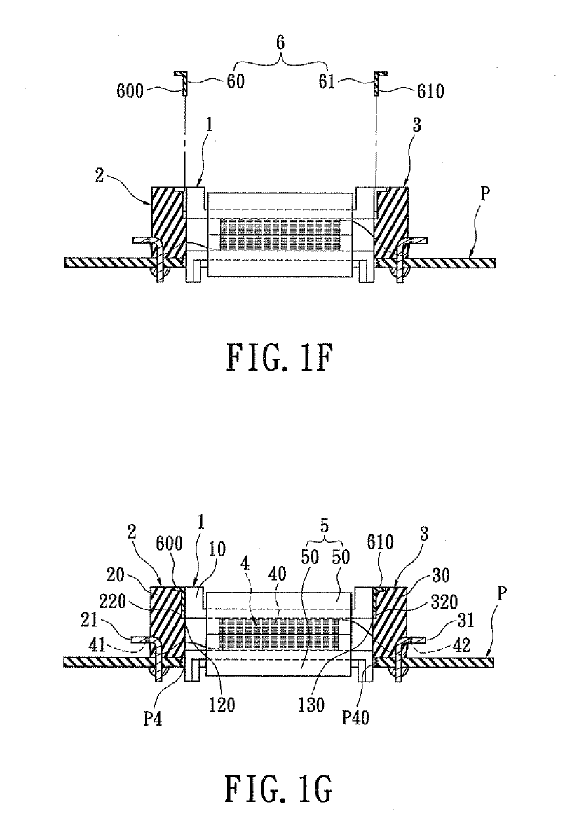

Referring to FIGS. 1A to 1G, the present invention provides a method of installing a movable transformer T, including the following steps:

The step S100 is that: referring to FIG. 1A, providing a PCB P; wherein the PCB P has a removing portion P1 (the removing portion P1 would be removed on follow-up step), and the removing portion P1 is connected with the PCB P via many connection portions P2. In other words, many holes P3 may be formed on the PCB P in order to form the removing portion P1 and the connection portions P2 connected between the PCB P and the removing portion P1.

The step S102 is that: referring to FIG. 1B, electrically connecting the movable transformer T to the PCB P; wherein the movable transformer T has a fixing unit electrically disposed on the PCB P, a movable unit disposed above the removing portion P1 and being movable relative to the fixing unit, a magnetic unit 5 jointed with the fixing unit and a winding unit 4 disposed around the fixing unit and the movable unit. In other words, the movable unit is a first bobbin unit 1, the fixing unit is composed of a second bobbin unit 2 and a third bobbin unit 3, and the magnetic unit 5 passes through the first bobbin unit 1 and is disposed outside the first bobbin unit 1.

The step S104 is that: referring to FIG. 1C, forming solder balls B to electrically connect many conductive pins 21 of the second bobbin unit 2 and many conductive pins 31 of the third bobbin unit 3 to the PCB P. In other words, the PCB P passes through a tin furnace in order to electrically fix the movable transformer T on the PCB P by the solder balls B.

The step S106 is that: referring to FIG. 1D, removing the removing portion P1 from the PCB P in order to form an opening P4 on the PCB P. In addition, the PCB P has a plurality of cutting marks P40 formed on an inner surface of the opening P4.

The step S108 is that: referring to FIG. 1E, pressing the movable unit (the first bobbin unit 1) to move downwards the movable unit relative to the fixing unit and receive the movable unit in the opening P4. In other words, one side of the first bobbin unit 1 is slidably mated with the second bobbin unit 2, another side of the first bobbin unit 1 is slidably mated with the third bobbin unit 3, so that the first bobbin unit 1 is selectively moved from one position above the opening P4 to another position in the opening P4.

The step S110 is that: referring to FIGS. 1F and 1G, fixing the position of the movable unit relative to the fixing unit by a retaining unit 6 after the step of pressing the movable unit (the step of S108). In other words, the first bobbin unit 1 may be pressed by the retaining unit 6 in order to tightly fix the first bobbin unit 1 between the second bobbin unit 2 and the third bobbin unit 3. Of course, the first bobbin unit 1 may be fixed between the second bobbin unit 2 and the third bobbin unit 3 without executing the step of S110.

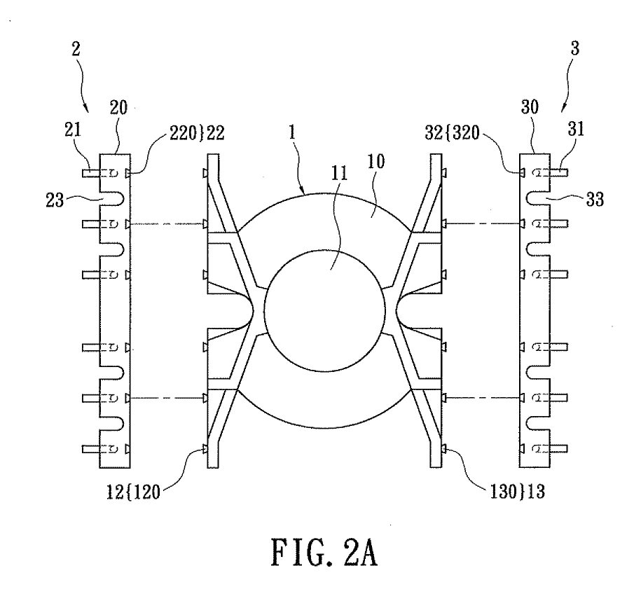

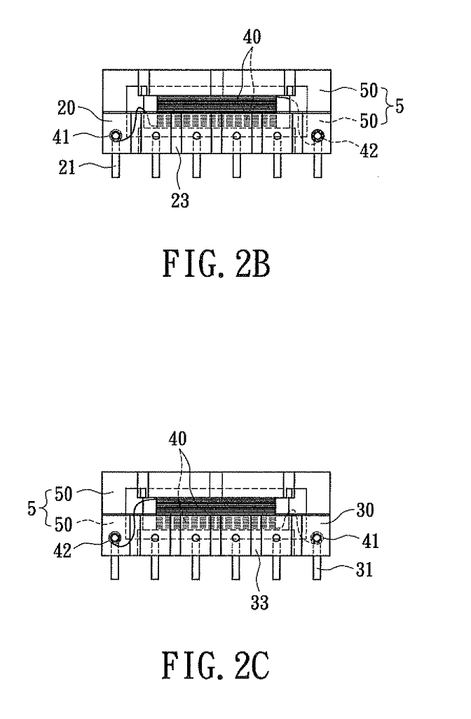

Referring to FIGS. 1F, 1G and 2A-2C, FIG. 2A shows a top, exploded, schematic view of the first, the second and the third bobbin units, FIG. 2B shows a lateral, schematic view of one side of the movable transformer, and FIG. 2C shows a lateral, schematic view of another side of the movable transformer. The present invention provides a movable transformer embedded into an opening P4 of a PCB P, including: a first bobbin unit 1, a second bobbin unit 2, a third bobbin unit 3, a winding unit 4 and a magnetic unit 5. The PCB P has a plurality of cutting marks P40 formed on an inner surface of the opening P4.

The second bobbin unit 2 is electrically connected to the PCB P. The third bobbin unit 3 is electrically connected to the PCB P. The winding unit 4 is disposed around the first bobbin unit 1, the second bobbin unit 2 and the third bobbin unit 3. The magnetic unit 5 passes through the first bobbin unit 1 and disposed outside the first bobbin unit 1. In addition, one side of the first bobbin unit 1 is slidably mated with the second bobbin unit 2, another side of the first bobbin unit 1 is slidably mated with the third bobbin unit 3, so that the first bobbin unit 1 is selectively moved from one position above the opening P4 to another position in the opening P4. The present invention provides an example shown as follows:

The first bobbin unit 1 has a first bobbin 10, a through hole 11 passing through the first bobbin 10, a first major retaining structure 12 disposed on one lateral side of the first bobbin 10, and a second major retaining structure 13 disposed on another lateral side of the first bobbin 10. In addition, the first major retaining structure 12 has a plurality of first protrusions 120, and the second major retaining structure 13 has a plurality of second protrusions 130.

The second bobbin unit 2 has a second bobbin 20, a plurality of first conductive pins 21 disposed on a bottom side of the second bobbin 20 and electrically embedded into the PCB P and a first minor retaining structure 22 slidably mated with the first major retaining structure 12. In addition, the second bobbin unit 2 has a plurality of first channels 23 (as shown in FIG. 2B) formed on the second bobbin 20, and one part of the winding unit 4 passes through the first channels 23. The first minor retaining structure 22 has a plurality of first grooves 220 for respectively receiving the first protrusions 120, each first groove 220 is a first wedge groove, and the wide of the first wedge groove gradually becomes smaller from top to bottom.

The third bobbin unit 3 has a third bobbin 30, a plurality of second conductive pins 31 disposed on a bottom side of the third bobbin 30 and electrically embedded into the PCB P and a second minor retaining structure 32 slidably mated with the second major retaining structure 13. In addition, the third bobbin unit 3 has a plurality of second channels 33 (as shown in FIG. 2C) formed on the third bobbin 30, and one part of the winding unit 4 passes through the second channels 33. The second minor retaining structure 32 has a plurality of second grooves 320 for respectively receiving the second protrusions 130, each second groove 320 is a second wedge groove, and the wide of the second wedge groove gradually becomes smaller from top to bottom.

The winding unit 4 has a first winding portion 40 disposed around the first bobbin 10, a second winding portion 41 extended from the first winding portion 40 to the second bobbin 20 and electrically connected to the first conductive pins 21, and a third winding portion 42 extended from the first winding portion 40 to the third bobbin 30 and electrically connected to the second conductive pins 31. Hence, the second winding portion 41 passes through the first channels 23, and the third winding portion 42 passes through the second channels 33.

The magnetic unit 5 is composed of at least two magnetic cores 50 that are abutted against each other. Each magnetic core 50 has an inner core portion received in the through hole 11 and an outer core portion connected to the inner core portion and covering one part of the first bobbin 10 and the winding unit 4. The two inner core portions of the two magnetic cores 50 are abutted against each other, and the two outer core portions of the two magnetic cores 50 are abutted against each other. In addition, the two magnetic cores 50 are respectively installed on a top side and a bottom side of the first bobbin unit 1. It means the magnetic unit 5 is a vertical type.

The retaining unit 6 has a first retaining structure 60 for fixing each first protrusion 120 in each first groove 220 and a second retaining structure 61 for fixing each second protrusion 130 in each second groove 320. The first retaining structure 60 has a plurality of first retaining portions 600 respectively embedded into the first grooves 220 and respectively abutted against the first protrusions 120, and the second retaining structure 61 has a plurality of second retaining portions 610 respectively embedded into the second grooves 320 and respectively abutted against the second protrusions 130. Hence, the first bobbin unit 1 may be tightly fixed between the second bobbin unit 2 and the third bobbin unit 3 by using the first retaining portions 600 and the second retaining portions 610.

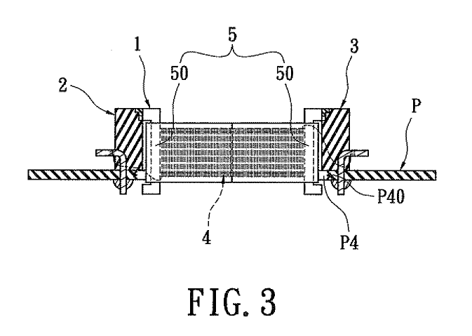

FIG. 3 shows a lateral, schematic view of the movable transformer embedded according to another embodiment of the present invention. Another embodiment of the present invention provides a movable transformer embedded into the opening P4 of the PCB P, including: a first bobbin unit 1, a second bobbin unit 2, a third bobbin unit 3, a winding unit 4 and a magnetic unit 5. The PCB P has a plurality of cutting marks P40 formed on an inner surface of the opening P4. The difference between FIG. 3 and FIG. 1G is that: the two magnetic cores 50 of the magnetic unit 5 are respectively installed on a left side and a right side of the first bobbin unit 1. It means the magnetic unit 5 is a horizontal type. In other words, no matter the magnetic unit 5 is a vertical type or a horizontal type, the two types of the magnetic unit 5 can be applied to the present invention in order to embed the movable transformer T into the opening P4 of the PCB P.

The above-mentioned descriptions merely represent solely the preferred embodiments of the present invention, without any intention or ability to limit the scope of the present invention which is fully described only within the following claims. Various equivalent changes, alterations or modifications based on the claims of present invention are all, consequently, viewed as being embraced by the scope of the present invention.

What is claimed is:

1. A movable transformer embedded into an opening of a PCB, comprising:
a first bobbin unit;
a second bobbin unit electrically connected to the PCB;
a third bobbin unit electrically connected to the PCB;
a winding unit disposed around the first bobbin unit, the second bobbin unit and the third bobbin unit; and
a magnetic unit passing through the first bobbin unit and disposed outside the first bobbin unit;
wherein one side of the first bobbin unit is slidably mated with the second bobbin unit, another side of the first bobbin unit is slidably mated with the third bobbin unit, so that the first bobbin unit is selectively moved from one position above the opening to another position in the opening.

2. The movable transformer as claimed in claim 1, wherein the first bobbin unit has a first bobbin, a through hole passing through the first bobbin, a first major retaining structure disposed on one lateral side of the first bobbin, and a second major retaining structure disposed on another lateral side of the first bobbin.

3. The movable transformer as claimed in claim 2, wherein the second bobbin unit has a second bobbin, a plurality of first conductive pins disposed on a bottom side of the second bobbin and electrically embedded into the PCB and a first minor retaining structure slidably mated with the first major retaining structure, wherein the third bobbin unit has a third bobbin, a plurality of second conductive pins disposed on a bottom side of the third bobbin and electrically embedded into the PCB and a second minor retaining structure slidably mated with the second major retaining structure.

4. The movable transformer as claimed in claim 3, wherein the winding unit has a first winding portion disposed around the first bobbin, a second winding portion extended from the first winding portion to the second bobbin and electrically connected to the first conductive pins, and a third winding portion extended from the first winding portion to the third bobbin and electrically connected to the second conductive pins.

5. The movable transformer as claimed in claim 4, wherein the second bobbin unit has a plurality of first channels formed on the second bobbin, the second winding portion passes through the first channels, the third bobbin unit has a plurality of second channels formed on the third bobbin, and the third winding portion passes through the second channels.

6. The movable transformer as claimed in claim 2, wherein the magnetic unit is composed of at least two magnetic cores that are abutted against each other.

7. The movable transformer as claimed in claim 2, wherein the first major retaining structure has a plurality of first protrusions, the second major retaining structure has a plurality of second protrusions, the first minor retaining structure has a plurality of first grooves for respectively receiving the first protrusions, and the second minor retaining structure has a plurality of second grooves for respectively receiving the second protrusions.

8. The movable transformer as claimed in claim 7, wherein each first groove is a first wedge groove, the wide of the first wedge groove gradually becomes smaller from top to bottom, each second groove is a second wedge groove, and the wide of the second wedge groove gradually becomes smaller from top to bottom.

9. The movable transformer as claimed in claim 7, further comprising: a retaining unit having a first retaining structure for fixing each first protrusion in each first groove and a second retaining structure for fixing each second protrusion in each second groove, wherein the first retaining structure has a plurality of first retaining portions respectively embedded into the first grooves and respectively abutted against the first protrusions, and the second retaining structure has a plurality of second retaining portions respectively embedded into the second grooves and respectively abutted against the second protrusions.

10. The movable transformer as claimed in claim 1, wherein the PCB has a plurality of cutting marks formed on an inner surface of the opening.

11. A method of installing a movable transformer, comprising:
providing a PCB, wherein the PCB has a removing portion;
electrically connecting the movable transformer to the PCB, wherein the movable transformer has a fixing unit electrically disposed on the PCB, a movable unit disposed above the removing portion and being movable relative to the fixing unit, a magnetic unit jointed with the fixing unit and a winding unit disposed around the fixing unit and the movable unit;
fixing the movable transformer on the PCB and removing the removing portion from the PCB in order to form an opening on the PCB; and
pressing the movable unit to move downwards the movable unit relative to the fixing unit and receive the movable unit in the opening.

12. The method as claimed in claim 11, wherein the movable unit is a first bobbin unit, the fixing unit is composed of a second bobbin unit and a third bobbin unit, the magnetic unit passes through the first bobbin unit and is disposed outside the first bobbin unit, wherein one side of the first bobbin unit is slidably mated with the second bobbin unit, another side of the first bobbin unit is slidably mated with the third bobbin unit, so that the first bobbin unit is selectively moved from one position above the opening to another position in the opening.

13. The method as claimed in claim 12, wherein the first bobbin unit has a first bobbin, a through hole passing through the first bobbin, a first major retaining structure disposed on one lateral side of the first bobbin, and a second major retaining structure disposed on another lateral side of the first bobbin.

14. The method as claimed in claim 13, wherein the second bobbin unit has a second bobbin, a plurality of first conductive pins disposed on a bottom side of the second bobbin and electrically embedded into the PCB and a first minor retaining structure slidably mated with the first major retaining structure, wherein the third bobbin unit has a third bobbin, a plurality of second conductive pins disposed on a bottom side of the third bobbin and electrically embedded into the PCB and a second minor retaining structure slidably mated with the second major retaining structure.

15. The method as claimed in claim 14, wherein the winding unit has a first winding portion disposed around the first bobbin, a second winding portion extended from the first winding portion to the second bobbin and electrically connected to the first conductive pins, and a third winding portion extended from the first winding portion to the third bobbin and electrically connected to the second conductive pins.

16. The method as claimed in claim 15, wherein the second bobbin unit has a plurality of first channels formed on the second bobbin, the second winding portion passes through the first channels, the third bobbin unit has a plurality of second channels formed on the third bobbin, and the third winding portion passes through the second channels.

17. The method as claimed in claim 13, wherein the magnetic unit is composed of at least two magnetic cores that are abutted against each other.

18. The method as claimed in claim 13, wherein the first major retaining structure has a plurality of first protrusions, the second major retaining structure has a plurality of second protrusions, the first minor retaining structure has a plurality of first grooves for respectively receiving the first protrusions, and the second minor retaining structure has a plurality of second grooves for respectively receiving the second protrusions.

19. The method as claimed in claim 18, wherein each first groove is a first wedge groove, the wide of the first wedge groove gradually becomes smaller from top to bottom, each second groove is a second wedge groove, and the wide of the second wedge groove gradually becomes smaller from top to bottom.

20. The method as claimed in claim 11, further comprising fixing the position of the movable unit relative to the fixing unit by a retaining unit after the step of pressing the movable unit.
